(19) United States
(12) Patent Application Publication
(10) Pub. No.: US 2014/0147635 A1
(43) Pub. Date: May 29, 2014

(54) COMPOSITE COATING MATERIAL AND THE PRODUCTION METHOD OF THE SAME

(71) Applicants: Chung-Ching Feng, Tainan Hsien (TW); I-Peng Yao, Tainan Hsien (TW); Pei-Huo Huang, Tainan Hsien (TW); Ko-Feng Wang, Tainan Hsien (TW); Yong-Song Lin, Tainan Hsien (TW); Kai-Feng Kang, Tainan Hsien (TW)

(72) Inventors: Chung-Ching Feng, Tainan Hsien (TW); I-Peng Yao, Tainan Hsien (TW); Pei-Huo Huang, Tainan Hsien (TW); Ko-Feng Wang, Tainan Hsien (TW); Yong-Song Lin, Tainan Hsien (TW); Kai-Feng Kang, Tainan Hsien (TW)

(21) Appl. No.: 13/688,237

(22) Filed: Nov. 29, 2012

(51) Int. Cl. H05K 5/03

(52) U.S. Cl. CPC H05K 5/03
USPC 428/160; 428/172

(57) ABSTRACT

A composite coating material for covering an electronic device includes a surface layer with a surface pattern printed by a release paper, said surface layer being an outer layer of said composite coating material; structure layer made of polyurethane (PU) material, said structure layer being a middle portion of said composite coating material, and connected to said surface layer; substrate layer made of polyurethane (PU) material, said substrate layer being a lower layer of said composite coating material and connected to said structure layer.

The present invention is a continuation in part (CIP) of U.S. patent application Ser. No. 11/418,914. Therefore, the contents of U.S. patent application Ser. No. 11/418,914 is incorporated into the present invention as a part of the present invention.

### FIELD OF THE INVENTION

The present invention relates to coating materials, more particularly to a composition and the production method of a coating material whose surface is colored and has a relief-like pattern for providing users with a better visual or touch effect when coated on the outer shells of electronic devices.

### BACKGROUND OF THE INVENTION

The outer shells of electronic devices in the market are made of a material selected from ABS plastics, magnesium alloy, carbon fibers and titanium alloy. The four materials for making the outer shells have respectively advantages and disadvantages, and the following is a comparison.

### The First Type: Fire-Resistant Plastic-ABS (Acrylonitrile Butadiene Styrene)

ABS is a copolymer made by polymerizing styrene and acrylonitrile in the presence of polybutadiene, which is properties of heat-resistance and solvent-resistance better than those of high impact polystyrene (HIPS) plastics. The ABS materials is further more reflective. Because of the strong polarity of the CN-group of acrylonitrile, the Polystyrene (PS) molecular chain is enhanced, thereby causing a impact strength, stretching strength and surface hardness of the resulted plastic objects better than high impact polystyrene (HIPS) plastics.

The higher the acrylonitrile content of a material is, the better the heat resistance, the rigidity and the anti-solvent property. Since the material of high acrylonitrile content is very stable, an object made of the ABS material has excellent mechanical property and particularly suitable for making plastic parts by injection molding for engineering purposes.

The ABS resin of high brilliance, shock-resistance and capable of being electroplated is used in home appliances and toys. The ABS of high fluidity is used in appliances of large size, motorcycle outer shells and products of thin shells. On the other hand, the ABS of low fluidity is used in producing slabs and tubes by injection molding, which is realized in the inner walls of refrigerators, briefcases, tubes and other large containers. The fire-proof ABS materials are used in making computer outer shells, computer accessories, electronic devices and business machines that need to satisfy UL94 standard. The heat-resistant ABS materials are used in making outer shells of heat-generating appliances, air blowers, heaters and automobile parts (such as meter panels).

However, despite high hardness and shock-resistance, ABS materials are inferior in heat conduction and dissipation compared with magnesium and titanium alloys. Further, their extension performance is mediocre, and therefore the extent the their outlooks may vary is limited. Overall, the outer shells made of ABS are cheap and fast to manufacture, but their toughness is not tough enough and cannot prevent electromagnetic wave leakage.

### The Second Type: Magnesium Alloy

The earliest use of magnesium alloy is in aerospace industry, in the year of 1808. Because of toughness, thermal conductivity and being easy to make modules, magnesium alloy is replacing aluminum steel and plastic in making electronic devices.

There many advantages of magnesium alloy as follows. They are: (1) good shielding effect of electromagnetic interference (because magnesium alloy is non-magnetic metal); (2) high thermal conductivity, good for heat dissipation of high-performance CPU; (3) light weight and good toughness (because the ratio of magnesium to aluminum is ⅓ and to iron ¼, the rigidity thereof higher than iron and aluminum); (4) high shock-absorbing property, with a damping capacity 10-25 times aluminum alloy, 1.5 times zinc alloy; (5) low deformability even it goes through a large temperature change; and (6) high production rate, because liquid magnesium alloy will solidify rapidly in a mold.

Magnesium, being the eighth most abundant element on the earth, has an almost unlimited supply. Magnesium alloy is traditionally used in automobile, bicycle and tool parts. Since it is of light weight and high thermal conductivity, it can be used in 3C products, such as computer outer shells.

A single magnesium alloy plate is about 1.0 mm, which is of high malleability and will succumb to a designed outlook. However, it has a high thermal conductivity, and it should be careful in handling the heat radiation during the manufacturing process.

Further, the casting of objects made of magnesium alloy has a high fault rate, and secondary processing is usually needed, such as anti-rust surface treatment and painting, which will largely increase labor cost.

### The Third Type: Carbon Fiber

In future, electronic devices made of carbon-fiber alloys may replace those made of magnesium alloys, whereby the devices will be lighter and more portable. Although, the magnesium alloy materials are currently predominating, they have some problems, such as the definite method of recycling.

The flexibility of carbon-fiber alloys can be significantly improved by the quantity of added carbon fibers to attain a level glass fibers cannot attain.

The carbon-fiber coating material can completely attain the requirement of light weight and be easily provided with surface patterns of various styles. Further, its toughness is twice of magnesium alloy (while weights only 80% thereof), and its shielding capability against electromagnetic waves is also superior.

However, even a carbon-fiber plate as thin as 1.2 mm, of good shock-absorbing and anti-erosion properties, a toughness twice of magnesium alloy, low deformability and especially high thermal conductivity, its strength being the outer shells of notebook computers is still mediocre.

### The Fourth Type: Titanium Alloy

Titanium alloys are initially widely used in aerospace industry. They have the advantages of light weight, high toughness, good shock-absorbing property, good malleability and good thermal conductivity. Therefore, titanium alloys are now widely used in daily life appliances. Because of its properties of heat-resistance and anti-erosion, artificial bones are made of titanium alloys too.

A plate of titanium alloy used to form the outer case of a notebook computer is as thin as 0.5 mm, 50% of that made of magnesium alloy. The titanium alloy computer case has much better heat radiation property and good malleability to accommodate various designs. Since the toughness is three to four times of magnesium alloy, the computer case made of titanium alloy is the lightest so far.

However, even with the advantages described above, the computer cases made of titanium alloys have the disadvantage of relatively fragile mechanical property due to the HCP crystal structure of titanium alloy. Therefore, the case cannot be made by die-casting and only by punching. Further, it can be formed piece by piece, which requires secondary processing of piece connections and therefore much higher production cost.

In summary, the outer cases of electronic devices are made of ABS plastic, magnesium alloy, carbon fiber and titanium alloy, of which magnesium and titanium alloys are most popular. The cases made of ABS plastic are of low production cost, since they can be formed at once by ejection molding, even there are many reinforcing rip structures and connection portions thereon. However, the ABS case cannot quite satisfy the requirement of toughness and shielding against the electromagnetic wave leakage. On the other hand, the magnesium alloy cases have a high fault ratio as produced by die-casting. Also, the secondary processing such as anti-rust surface treatment will cost extra manpower. The computer cases made of titanium alloys have the disadvantage of relatively fragile mechanical property due to the HCP crystal structure of titanium alloy. Therefore, the case cannot be made by die-casting and only by punching. Further, it can be formed piece by piece, which requires secondary processing of piece connections and therefore much higher production cost.

Moreover, outer shells of electronic devices are usually made of metallic materials, such as magnesium and titanium alloys. Therefore, the feeling of touching them is hard and cold. It is also difficult to produce a relief pattern on a shell for enhancing holding.

It is less friendly to the environment that the production of metallic cases such as magnesium alloy needs secondary treatments in which chemical solvents are extensively used, therefore producing pollutants to the environment at the same time.

### SUMMARY OF THE INVENTION

The primary objective of the present invention is to provide a composite coating material and the production method of the same, which is cheap to manufacture and may have various colors and surface relief-like patterns. Therefore, the devices coated with the material are easier to hold and more visually appealing.

Compared with metallic or carbon-fiber outer shells, the devices coated by a polyurethane (PU) layer is warm and soft. The surface of the layer is easier to form a relief pattern, without using the expensive techniques of erosive carving. Therefore, devices coated by the material as disclosed by the present invention are easier to hold.

The present invention is also for solving the restrictions of the conventional coating materials, such as ABS plastics, magnesium alloy, carbon fibers and titanium alloy. The following is a brief description of polyurethane (PU) material.

The main polyurethane producing reaction is between a diisocyanate (aromatic and aliphatic types are available) and a polyol, typically a polyethylene glycol or polyester polyol, in the presence of catalysts and materials for controlling the cell structure, (surfactants) in the case of foams. Polyurethane can be made in a variety of densities and hardnesses by varying the type of monomer(s) used and adding other substances to modify their characteristics, notably density, or enhance their performance. Other additives can be used to improve the fire performance, stability in difficult chemical environments and other properties of the polyurethane products.

The properties of the polyurethane resin are determined mainly by the choice of polyol, which produces soft segments therein. There are further hard segments reduced by Diisocyanate, resulting in phase separation and the island-like crystallization appearing in the PU material. Thereby, the PU material at room temperature will exhibit the phenomenon of physical crosslink, which will enhance its mechanical property, despite a molecular weight of tens of thousands.

Polyurethane (PU) is used to make soft and hard foamed plastic materials, structural materials, flexible artificial leathers and other thermosetting flexible materials, which can be applied in the following areas:
A. automobile industry for making parts such as car seats, bumpers, mudguards, steering wheels, meter panels and car roofs;
B. architecture industry for making parts such as house roofs and heat-insulating plates;
C. soft foamed plastic industry for making parts such as matrices and beds;
D. artificial leather and flexible resin industry for making parts such as shoe soles, protective coating for concrete structures, tracks, coating for electronic devices, furniture pieces, ski boards and artificial leathers;
E. insulating material industry for making parts such as refrigerators, freezer containers, water-proof materials applied on house roofs and gas pipelines;
F. soft foamed plastic industry for making sofas.

The production method of the present invention includes adding dye agent into the liquid PU material to achieve a desired color at the outer surface. A release paper is also used for providing a relief pattern on the composite material. Since PU material feels warm, the coating material thereby produced is not only friendly to touch but also visually appealing. Further, the sponge-like inner layer of the coating material makes the present invention thicker, more water-resistant and noise-reducing.

To summarize, the present invention is to provide a PU coating material and the production method of the same, which is cheap to manufacture and may have various colors and surface relief-like patterns. In replacement of the current coating materials such as ABS and metallic alloys, devices coated by the present invention are easier to hold and more visually appealing.

As shown in FIG. 1, the structure of the present invention comprises a PU surface layer 120 having a selective color and relief-like pattern, a PU structure layer 130 which can be sponge-like or foam-free and a substrate layer 140.

Referring to FIG. 2, the second preferred embodiment of the present invention comprises a polyurethane (PU) surface layer having a colored surface pattern 120, a sponge-like structure layer 131 made of polyurethane (PU) material with foam agent and a substrate layer 140, as shown in FIG. 2. The third preferred embodiment of the present invention comprises a colored polyurethane (PU) surface layer 120 with a pattern, a polyurethane (PU) foam-free structure layer 132, a sponge-like structure layer 131 and a substrate layer 140, as shown in FIG. 3. The foam-free structure layer 132 is right above the substrate layer 140. The fourth preferred embodiment of the present invention comprises a colored polyurethane (PU) surface layer 120 with a pattern, a polyurethane (PU) foam-free structure layer 132, a sponge-like structure layer 131 and a substrate layer 140, as shown in FIG. 4. The fifth preferred embodiment of the present invention comprises a polyurethane (PU) surface layer 120 and a substrate layer 140, as shown in FIG. 5.

### BRIEF DESCRIPTION OF THE DRAWINGS

FIG. 1 is a cross-sectional view of the first preferred embodiment of the present invention.

FIG. 2 is a cross-sectional view of the second preferred embodiment of the present invention.

FIG. 3 is a cross-sectional view of the third preferred embodiment of the present invention.

FIG. 4 is a cross-sectional view of the fourth preferred embodiment of the present invention.

FIG. 5 is a cross-sectional view of the fifth preferred embodiment of the present invention.

### DETAILED DESCRIPTION OF THE PREFERRED EMBODIMENTS

The various objects and advantages of the present invention will be more readily understood from the following detailed description when read in conjunction with the appended drawings.

### The First Preferred Embodiment

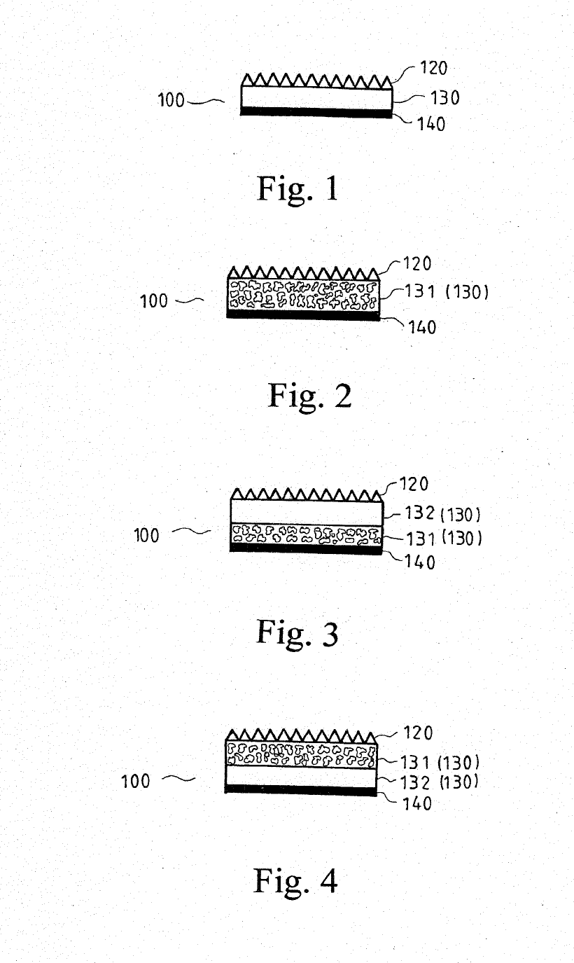

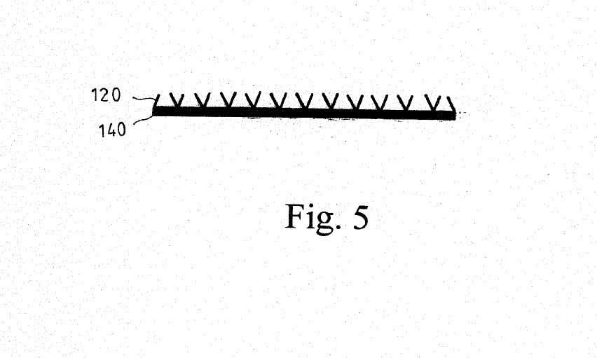

A release paper with a surface pattern is applied with a colored polyurethane (PU) layer and is then dried. When the release paper covered by the polyurethane (PU) layer is dry, another polyurethane (PU) layer is applied and dried to form a structure layer 130. A third polyurethane (PU) layer is applied to form a substrate layer 140. The composite structure on the release paper goes through processes of drying, rolling and forming to further form a surface layer 120 after the release paper is taken away. Thereby, a polyurethane (PU) layer having a colored surface pattern for covering the outer surface of an electronic device is formed, as shown in FIG. 1. The thickness of the PU layer is 0.5 mm. The second PU layer has a pore ratio of 0%. The hardness of the composite PU layer is ShoreA: 60.

### The Second Preferred Embodiment

A release paper with a surface pattern is applied with a colored polyurethane (PU) layer and is then dried. When the release paper covered by the polyurethane (PU) layer is dry, another polyurethane (PU) layer added with foam agent is applied thereon and dried to form a sponge-like structure layer 131. A third polyurethane (PU) layer is applied to form a substrate layer 140. The composite structure on the release paper goes through processes of drying, rolling and forming to further form a surface layer 120 after the release paper is taken away. Thereby, a polyurethane (PU) layer having a colored surface pattern for covering the outer surface of an electronic device is formed, as shown in FIG. 2. The thickness of the PU layer is 0.7 mm. The second PU layer has a pore ratio of 40%. The hardness of the composite PU layer is ShoreA: 30.

### The Third Preferred Embodiment

A release paper with a surface pattern is applied with colored polyurethane (PU) layer and is then dried. When the release covered by the polyurethane (PU) layer is dry, another polyurethane (PU) layer is applied thereon and dried to form a foam-free structure layer 132. A third polyurethane (PU) layer, added with foam agent, is then applied to form sponge-like structure layer 131. It is then applied with a final polyurethane (PU) layer to form a substrate layer 140. The composite structure on the release paper goes through processes of drying, rolling and forming to further form a surface layer 120 after the release paper is taken away. Thereby, a composite polyurethane (PU) layer having a colored surface pattern for covering the outer surface of an electronic device is formed, as shown in FIG. 3, wherein the middle structure layer 130 consists of the sponge-like structure layer 131 and the foam-free structure layer 132 adjacent to the surface layer 120. The thickness of the PU layer is 0.6 mm. The second PU layer has a pore ratio of 0%. The hardness of the composite PU layer is ShoreA: 40.

### The Fourth Preferred Embodiment

release paper with a surface pattern is applied with a colored polyurethane (PU) layer and is then dried. When the release paper covered by the polyurethane (PU) layer is dry, another polyurethane (PU) layer, added with foam agent, is applied thereon and dried to form a sponge-like structure layer 131. A third polyurethane (PU) layer is then applied to form foam-free structure layer 132. It is then applied with a final polyurethane (PU) layer to form a substrate layer 140. The composite structure on the release paper goes through processes of drying, rolling and forming to further form a surface layer 120 after the release paper is taken away. Thereby, composite polyurethane (PU) layer having a colored surface pattern for covering the outer surface of an electronic device is formed, as shown in FIG. 3, wherein the middle structure layer 130 consists of the foam-free structure layer 132 and the sponge-like structure layer 131 adjacent to the surface layer 120. The thickness of the PU layer is 0.6 mm. The sponge-like PU structure layer 131 has a pore ratio of 70%. The foam-free PU structure layer 132 has a pore ratio of 0%. The hardness of the composite PU layer is ShoreA: 35.

### The Fifth Preferred Embodiment

release cloth with a surface pattern is applied with a polyurethane (PU) layer of wet type and is immersed into water till the PU layer is condensed. The PU layer is then washed (by water), dried, rolled, surface-treated and then removed from the release cloth, forming a fur-like skin for covering the outer surface of an electronic device. The thickness of the PU layer is 0.4 mm. The PU structure layer has a pore ratio of 30%. The hardness of the composite PU layer is ShoreA: 15.

The present invention is thus described, and it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A composite coating material for covering an electronic device, comprising:
a surface layer with a surface pattern printed by a release paper, said surface layer being an outer layer of said composite coating material;
a structure layer made of polyurethane (PU) material, said structure layer being a middle portion of said composite coating material, and connected to said surface layer; and
a substrate layer made of polyurethane (PU) material, said substrate layer being a lower layer of said composite coating material and connected to said structure layer.

2. The composite coating material of claim 1 wherein said structure layer is a sponge-like polyurethane (PU) layer.

3. The composite coating material of claim 2 wherein said sponge-like polyurethane (PU) layer has a pore ratio less than 90%.

4. The composite coating material of claim 1 wherein said structure layer is a foam-free polyurethane (PU) layer.

5. The composite coating material of claim 1 wherein said structure layer consists of a sponge-like polyurethane (PU) layer and a foam-free polyurethane (PU) layer.

6. The composite coating material of claim 5 wherein said composite structure layer has a pore ratio less than 90%.

7. The composite coating material of claim wherein said surface layer is colored.

8. The composite coating material of claim 1 wherein said composite coating material has a thickness between 0.1˜1.0 mm.

9. The composite coating material of claim 1 wherein said composite coating material has a hardness ranging from ShowA: 10 to ShoreA: 90.

10. The composite coating material of claim 1 wherein said composite coating material is used on outer shells of notebook computers, mobile phones, personal data assistants (PDA), MP3 audio devices, thin televisions and digital cameras.
